(19) United States
(12) Patent Application Publication
(10) Pub. No.: US 2015/0331034 A1
(43) Pub. Date: Nov. 19, 2015

(54) PROBLEM DETECTION IN CABLE SYSTEM

(71) Applicant: KONINKLIJKE PHILIPS N.V., Eindhoven (NL)

(72) Inventors: HONG CHEN, SHANGHAI (CN); XIAOBO JIANG, SHANGHAI (CN)

(21) Appl. No.: 14/653,087

(22) PCT Filed: Nov. 11, 2013
(86) PCT No.: PCT/IB2013/060047

§ 371 Date: Jun. 17, 2015

(30) Foreign Application Priority Data
Dec. 18, 2012 (CN) PCT/CN2012/086849

(51) Int. Cl. G01R 31/08

(52) U.S. Cl. CPC G01R 31/083

(57) ABSTRACT

Devices (1) for detecting problems in cable systems with cables (4) and loads (5-8) comprise first circuits (11) for providing first signals to the cables (4), second circuits (12) for measuring parameters of second signals that are responses to the first signals, and third circuits (13) for detecting the problems in response to changes in values of the parameters. The loads (5-8) may comprise mutually parallel loads each showing a capacitive behavior. The problems may comprise interruptions in the cables (4) that result in changes in capacitances of the cable system and in the changes in the values of the parameters. The devices (1) may further comprise fourth circuits (14) for discharging the capacitances, fifth circuits (15) for deriving positions of the problems from the changes in the values of the parameters, and sixth circuits (16) for feeding at least one other circuit (11-15) and/or for activating at least one other circuit (11-15) in response to cable system information and/or timing information.

### FIELD OF THE INVENTION

The invention relates to a device for detecting a problem in a de-activated cable system, the cable system comprising a cable and loads connected to the cable. The invention further relates to a system comprising a device, to a method, to a computer program product and to a medium.

Examples of such a problem in a de-activated cable system are thefts of parts of the cable system. Examples of such a system are stations, cables and/or loads. Examples of such loads are lamps and other units that need to be supplied/powered/fed electrically.

### BACKGROUND OF THE INVENTION

CN 201867910 U discloses a street light cable anti-theft system wherein a front end control box is located near a first street light and wherein a signal control box is located near a last street light for monitoring a cable between the first and last street lights. These two boxes at two different locations are considered to be relatively disadvantageous.

CN 101635077 A discloses an anti-theft detection method for a road lamp cable wherein a variable frequency input current signal is injected into the cable and wherein output current signals and output voltage signals are to be measured for different frequencies of the input current signal and wherein resonance frequencies of road lamps are to be taken into account and wherein a number of actual road lamps needs to be known. This way, in a relatively complex way, two boxes at two different locations are no longer required, to monitor the cable.

### SUMMARY OF THE INVENTION

It is an object of the invention to provide a relatively simple device. Further objects of the invention are to provide a relatively simple system, and to provide a relatively simple method, computer program product and medium.

According to a first aspect, a device is provided for detecting a problem in a de-activated cable system, the cable system comprising a cable and loads connected to the cable, the device comprising
a first circuit for providing a first signal to the cable,
a second circuit for measuring a parameter of a second signal, the second signal being a response to the first signal, and
a third circuit for detecting the problem in the cable system in response to a change in a value of the parameter of the second signal.

A de-activated cable system is a non-operating cable system that has been switched off/shut down. In such a de-activated cable system, any signals for supplying/powering/feeding the loads electrically are not present. For example, for loads in the form of street lamps, during the day, when there is a sufficient amount of natural daylight, these street lamps will be switched off/shut down, and the cable system will be non-operating. The street lamps comprise those lamps driven by driver or ballast, such as LED lamp, HPS (High Pressure Sodium), Fluorescent Lamp, CFL(Compact Fluorescent Lamp), HID (High Intensity Discharger) etc, each show a capacitive behavior in the de-activated cable system.

The first circuit provides the first signal to the cable, the second circuit measures the parameter of the second signal that is a response to the first signal, and the third circuit detects the problem in the cable system in response to a change in the value of the parameter of the second signal. As a result, compared to CN 101635077 A, that is relatively complex, a relatively simple device for detecting a problem in a de-activated cable system has been created.

Compared to CN 201867910 U, the improved device does not need to boxes at two different locations, to monitor the cable.

Compared to CN 101635077 A, the improved device does not need a variable frequency input current signal, does not need to measure output current signals and output voltage signals for different frequencies of the input current signal, does not need to take into account resonance frequencies of road lamps, and does not need to know a number of actual road lamps.

The measuring of the parameter of the second signal may comprise an absolute measurement/determination or a relative measurement/determination.

An embodiment of the device is defined by the loads comprising mutually parallel loads electrically connected to the cable at mutually different locations, the mutually parallel loads each showing a capacitive behavior in the de-activated cable system. In a cable system comprising mutually parallel loads each showing a capacitive behavior, a capacitance of the cable system may be considered to correspond with a sum of the load capacitances.

An embodiment of the device is defined by the problem in the cable system comprising an interruption in the cable of the cable system, the interruption resulting in a change in a capacitance of the cable system at said device, the change in the capacitance of the cable system at said device resulting in the change in the value of the parameter of the second signal. In a cable system comprising an interruption in the cable, the load capacitances of the loads present between the device and the interruption will still contribute to the capacitance of the cable system at said device, the load capacitances of the other loads will not. Other problems that can be detected via the device are an interruption in a connection between the cable and one of the loads and a malfunction in one of the loads that results in a changed capacitive behavior of this load etc.

An embodiment of the device is defined by further comprising
a fourth circuit for discharging the capacitance. Preferably, the capacitance of the cable system is to be discharged at a centralized location via the fourth circuit, before the first signal is provided to the cable and before the parameter of the second signal is measured etc. Alternatively, the capacitance of the cable may be discharged at decentralized locations, for example via resistors connected in parallel to the loads, but such resistors will increase a power consumption of the cable system.

An embodiment of the device is defined by further comprising
a fifth circuit for deriving a position of the problem from the change in the value of the parameter of the second signal. Preferably, the parameter of the second signal is chosen such that a position of the problem such as the interruption can be derived from the change in the value of the parameter.

An embodiment of the device is defined by the first circuit being arranged to provide the first signal to the cable at first and second moments in time, the second circuit being arranged to measure the parameter of the second signal per moment in time, and the third circuit being arranged to compare values of this parameter of the second signal with each other. Preferably, values of the parameter of the second signal are compared with each other, to detect the problem in the cable system, and to avoid that the device needs to be provided with knowledge about a normal value of the parameter in advance. In case the change in the capacitance of the cable system at said device results in the change in the value of the parameter of the second signal, between the first and second moments in time, this capacitance should be discharged sufficiently. This may for example be done via the fourth circuit or via resistors connected in parallel to the loads or through natural discharge etc.

An embodiment of the device is defined by the first signal comprising a DC current signal and the second signal comprising a voltage signal. This is a simple, low cost and robust embodiment.

An embodiment of the device is defined by the DC current signal having a constant amplitude and the voltage signal comprising a slope. This is a simple, low cost and robust embodiment.

An embodiment of the device is defined by the parameter of the voltage signal defining an angle of the slope or defining an amount of time required for an amplitude of the voltage signal to change by a predefined value. This is a simple, low cost and robust embodiment.

An embodiment of the device is defined by the first circuit being arranged to provide the DC current signal to the cable at a first and second moments in time, the second circuit being arranged to measure the parameter of the voltage signal per moment in time, and the third circuit being arranged to compare values of this parameter of the voltage signal with each other. Preferably, values of the parameter of the second signal are compared with each other, to detect the problem in the cable system, and to avoid that the device needs to be provided with knowledge about a normal value of the parameter in advance.

An embodiment of the device is defined by further comprising
a sixth circuit for feeding one or more of the other circuits and/or for activating one or more of the other circuits in response to cable system information and/or timing information. In a de-activated cable system, any signals for supplying/powering/feeding the loads electrically are not present. Therefore, the first, second, third, fourth and fifth circuits may need to be fed via an alternative way. Further, to avoid a collision between the signals for supplying/powering/feeding the loads electrically on the one hand and the first and second signals on the other hand, the device may need to be informed, for example via the cable system information (is the cable system activated or de-activated?) and/or via the timing information (what time is it?). Thereto, the sixth circuit may comprise a receiver for receiving such information and/or a detector for detecting such information.

According to a second aspect, a system is provided comprising the device as defined above and further comprising a station, a cable and/or a load.

According to a third aspect, a method is provided for detecting a problem in a de-activated cable system, the cable system comprising a cable and loads connected to the cable, the method comprising steps of
providing a first signal to the cable,
measuring a parameter of a second signal, the second signal being a response to the first signal, and
detecting the problem in the cable system in response to a change in a value of the parameter of the second signal.

According to a fourth aspect, a computer program product is provided for, when run on a computer, performing the steps of the method as defined above.

According to a fifth aspect, a medium is provided for storing and comprising the computer program product as defined above.

A basic idea is that that, to detect a problem in a cable system comprising a cable and loads, it should be sufficient to provide a first signal to the cable, to measure a parameter of a second signal that is a response to the first signal, and to detect the problem in the cable system in response to a change in a value of the parameter of the second signal.

A problem to provide an improved device has been solved. A further advantage is that the improved device is simple, low cost and robust.

These and other aspects of the invention will be apparent from and elucidated with reference to the embodiments described hereinafter.

### BRIEF DESCRIPTION OF THE DRAWINGS

In the drawings:

FIG. 1 shows a cable system and a device,

FIG. 2 shows an embodiment of the device,

FIG. 3 shows an analysis of the cable system,

FIG. 4 shows first waveforms,

FIG. 5 shows second waveforms, and

FIG. 6 shows a flow chart.

### DETAILED DESCRIPTION OF EMBODIMENTS

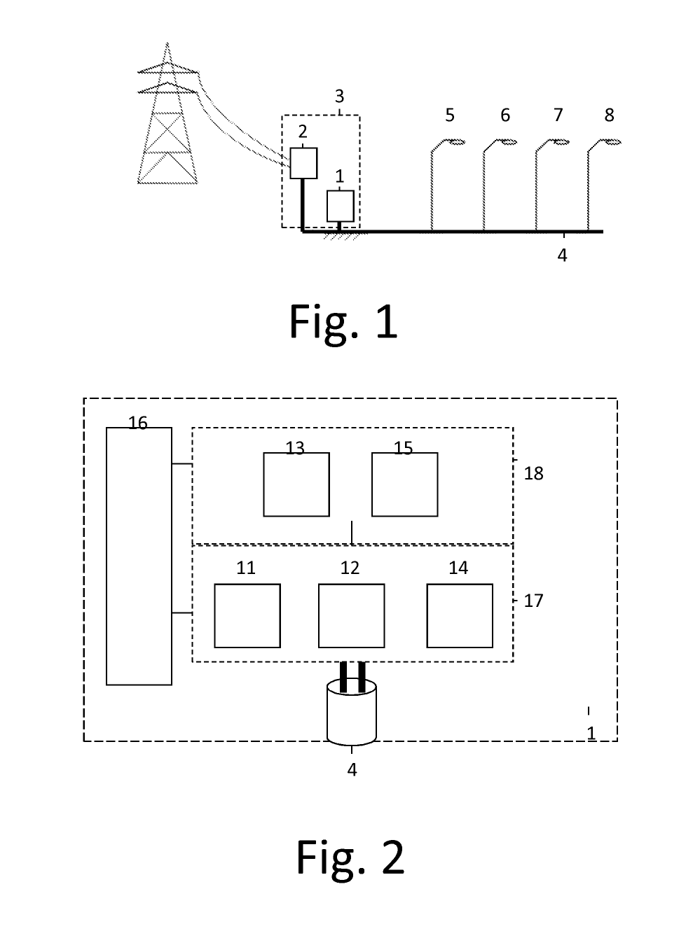

In the FIG. 1, a cable system and a device 1 are shown. The cable system comprises a cable 4 and loads 5-8 here in the form of street lamps, but other kinds of loads are not to be excluded. The cable 4 is connected to a box 2 in a station 3 comprising a converter for converting a transport voltage into a consumption voltage. The box 2 further comprises a switch for switching on the loads 5-8 when there is an insufficient amount of natural light and for switching off the loads 5-8 when there is a sufficient amount of natural light.

Alternatively, for example in case the consumption voltage is already offered to the station 3, the box 2 does not need to comprise the converter and may mainly comprise the switch.

The station 3 further comprises a device 1 for detecting a problem in a de-activated cable system, alternatively the device 1 may be located outside the station 3. In a de-activated cable system, the loads 5-8 have been switched off.

In the FIG. 2, an embodiment of the device 1 is shown. The device 1 comprises a first circuit 11 for providing a first signal to the cable 4, a second circuit 12 for measuring a parameter of a second signal, the second signal being a response to the first signal, and a third circuit 13 for detecting the problem in the cable system in response to a change in a value of the parameter of the second signal. The first and second circuits 11 and 12 may for example form part of an interface 17 connected to the cable 4, and the third circuit 13 may for example form part of a controller 18 connected to the interface 17. Alternatively, the first, second and third circuits 11-13 may be individual units that do not form part of a larger entity. Further alternatively, the first, second and third circuits 11-13 may form part of the controller 18 that further may have some kind of interface function, or the first, second and third circuits 11-13 may form part of the interface 17 that further may have some kind of controller function.

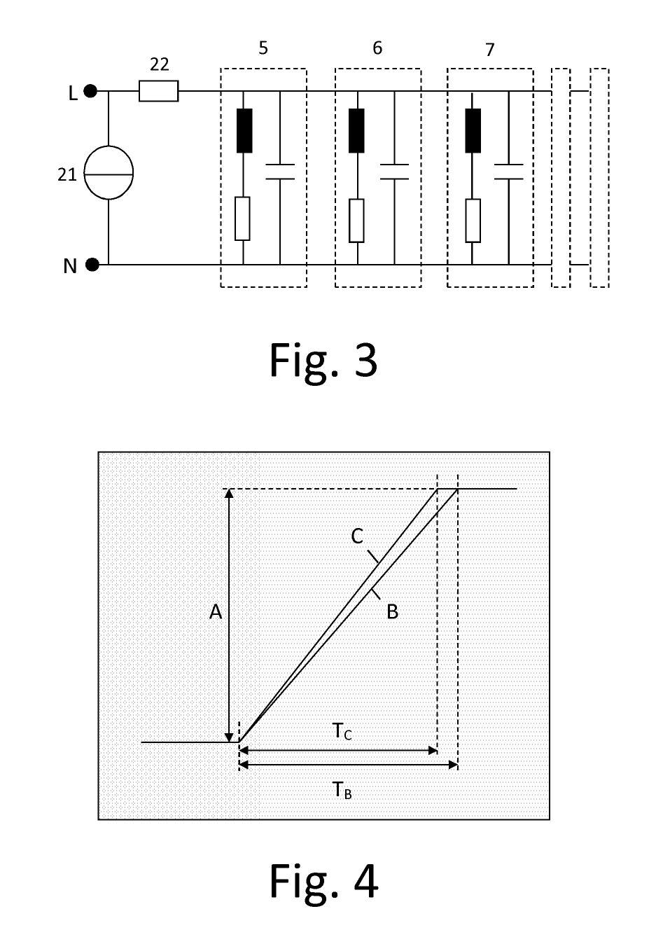

The cable 4 comprises two conductors, alternatively the cable 4 may comprise one conductor, with the other conductor being realized through a ground connection. In the FIG. 3, an analysis of the cable system is shown. The loads 5-7 may each be represented by a parallel connection of a capacitor and a serial connection, which serial connection comprises a resistor and an inductor, whereby the resistor may have a relatively high value such that the serial connection in approximation may be ignored here. The first circuit 11 may comprise a current source 21, and the cable 4 may be represented by a resistor 22. Fewer or more loads are clearly not to be excluded.

Preferably, the loads 5-8 comprise mutually parallel loads electrically connected to the cable 4 at mutually different locations, the mutually parallel loads each showing a capacitive behavior in the de-activated cable system. The problem in the cable system may comprise an interruption in the cable 4 of the cable system, the interruption resulting in a change in a capacitance of the cable system at said device 1, the change in the capacitance of the cable system at said device 1 resulting in the change in the value of the parameter of the second signal. An interruption in an activated cable system, wherein the loads 5-8 are switched on, will be visible immediately. Therefore, mainly in a de-activated cable system, wherein the loads 5-8 are switched off, such an interruption will need to be detected.

Preferably, the device 1 shown in the FIG. 2 may further comprise a fourth circuit 14 for discharging the capacitance, for example by short-circuiting the conductors of the cable 4. The fourth circuit 14 may form part of the interface 17 or of the controller 18 or may be an individual unit that does not form part of a larger entity.

Preferably, the device 1 shown in the FIG. 2 may further comprise a fifth circuit 15 for deriving a position of the problem such as the interruption from the change in the value of the parameter of the second signal. The fifth circuit 15 may form part of the controller 18 or of the interface 17 or may be an individual unit that does not form part of a larger entity.

Preferably, the first circuit 11 may be arranged to provide the first signal to the cable 4 at first and second moments in time, and the second circuit 12 may be arranged to measure the parameter of the second signal per moment in time, and the third circuit 13 may be arranged to compare values of this parameter of the second signal with each other. By repeatedly providing the first signal and measuring the parameter of the second signal, a sudden change in a value of the parameter will be an indication for a sudden interruption in the cable 4.

As an example only, the first signal may comprise a DC current signal I and the second signal may comprise a voltage signal U, that, in view of the FIG. 3, may be a response to the DC current signal I in accordance with an equation I/C=AU/At wherein C is a capacitance of the cable system at said device 1 and t is the time. Preferably, the DC current signal may have a constant amplitude and the voltage signal may comprise a slope, i.e. it's a time-related signal and the waveform of the voltage is a slope. The parameter of the voltage signal defines an angle of the slope or defines an amount of time required for an amplitude of the voltage signal to change by a predefined value. Also in this case, the first circuit 11 may be arranged to provide the DC current signal to the cable repeatedly, the second circuit 12 may be arranged to measure the parameter of the voltage signal repeatedly, and the third circuit 13 may be arranged to compare values of this parameter of the voltage signal with each other. When providing and measuring repeatedly, between two provisions/measurements, the capacitance of the cable system should be discharged sufficiently. This may for example be done via the fourth circuit 14 or via resistors connected in parallel to the loads 5-8 or through natural discharging etc.

Preferably, the device 1 shown in the FIG. 2 may further comprise a sixth circuit 16 for feeding one or more of the other circuits 11-15 and/or for activating one or more of the other circuits 11-15 in response to cable system information and/or timing information. Via cable system information, the device 1 can be informed about the cable system being activated or de-activated. Via timing information, the device 1 can be informed about the time. The sixth circuit 16 may further be coupled to the box 2 via a coupling not shown in the FIGS. 1 and 2 for receiving the feeding power and/or the information.

In the FIG. 4, first waveforms are shown. For the first signal in the form of the DC current signal, the second signal may be in the form of the voltage signal B and C. Each time the DC current signal is injected into the cable system, under the condition that the capacitance of the cable system at the device 1 has been sufficiently discharged before the injection, the voltage signal B will start rising from zero until an upper limit has been reached (this limit is here equal to an amplitude value A shown in the FIG. 4). This will take an amount of time T_{B}. When suddenly the voltage signal C is rising more quickly than usual, taking an amount of time T_{C}<T_{B}, it will be clear that the amount of capacitance of the cable system at the device 1 has been reduced. This will be an indication that an interruption in the cable 4 has been made, and an alarm for cable theft may be generated.

The parameter of the voltage signal here defines an amount of time required for an amplitude of the voltage signal to change by a predefined value (in this case the amplitude value A). Alternatively, the parameter of the voltage signal may define an angle of the slope of the voltage signal. In both cases, the relative change in the amount of time or in the slope will be proportional to the relative change in capacitance. For example, in case the amount of time is deceased by 10%, then about 10% of the capacitance will be missing, and this will correspond to a last 10% of the loads being cut off. This way, an estimation of the position of the interruption can be made. For example, for loads are in form of street lamps, if 10% capacitance reduced, it means 10% of lamps are off from system, that is, the 10% cable is off from system.

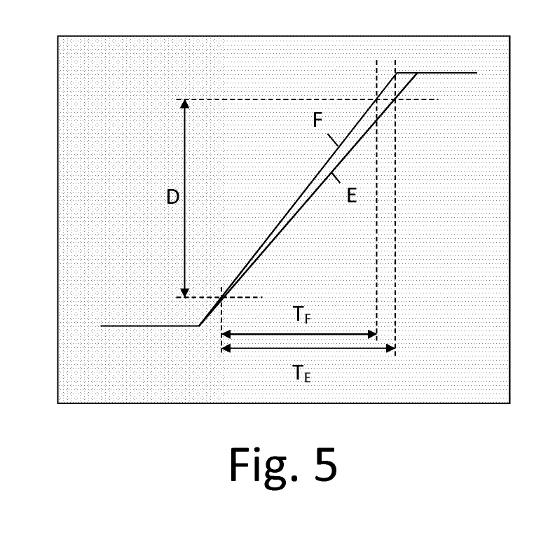

In the FIG. 5, second waveforms are shown. For the first signal in the form of the DC current signal, the second signal may be in the form of the voltage signal E and F. Each time the DC current signal is injected into the cable system, under the condition that the capacitance of the cable system at the device 1 has been sufficiently discharged before the injection, the voltage signal E will start rising from zero until an upper limit has been reached. To go from for example 10% to for example 90% of this limit (80% of this limit is then equal to an amplitude value D shown in the FIG. 5), it will take an amount of time T_{E}. When suddenly the voltage signal F is rising more quickly than usual, taking an amount of time T_{F}<T_{E}, it will be clear that the amount of capacitance of the cable system at the device 1 has been reduced. This will be an indication that an interruption in the cable 4 has been made, and an alarm for cable theft may be generated. Similarly as described before, an estimation of the position of the interruption can be made.

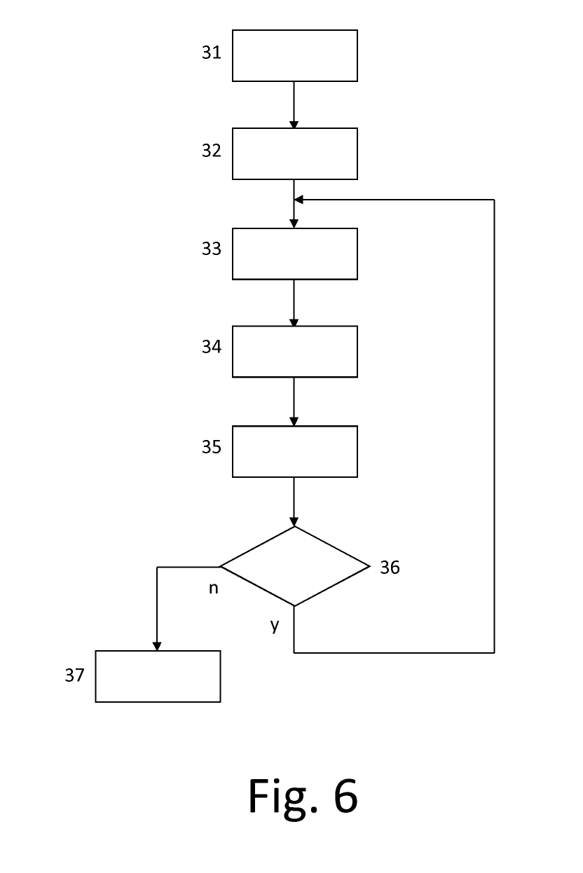

In the FIG. 6, a flow chart is shown, wherein the following blocks have the following meaning:
Block 31: A first signal is provided to a cable 4 of a de-activated cable system, the cable system comprising the cable 4 and loads 5-8, the loads 5-8 comprising mutually parallel loads electrically connected to the cable 4 at mutually different locations, the mutually parallel loads each showing a capacitive behavior in the de-activated cable system, a problem in the cable system comprising an interruption in the cable 4 of the cable system, the interruption resulting in a change in a capacitance of the cable system.
Block 32: A parameter of a second signal is measured, the second signal being a response to the first signal, the change in the capacitance of the cable system resulting in a change in a value of the parameter of the second signal.
Block 33: The capacitance is discharged.
Block 34: The first signal is provided again to the cable 4 of the de-activated cable system.
Block 35: The parameter of the second signal is then measured again.
Block 36: Compare the last two measured values of the parameter of the second signal, are they relatively equal (yes), go to block 33, if not relatively equal (no), go to block 37.
Block 37: Detect the problem in the cable system in response to the change in the value of the parameter of the second signal, further a position of the problem may be derived, or not, and an alarm may be generated, or not.

The flow chart shown in the FIG. 6 is an example only. The mutually parallel loads 5-8 may each show another kind of behavior in the de-activated cable system than the capacitive behavior. The discharging of the capacitance may be realized otherwise, for example via resistors connected in parallel to the loads 5-8 or through natural discharging etc. And above and before the block 31, another discharging may be performed, to be sure that the capacitance is fully discharged, before the first signal is provided in block 31 etc.

Other kinds of first and second signals are not to be excluded. For example for mutually parallel loads each showing an inductive behavior, the first signal may be a voltage signal U and the second signal may be a current signal I, in accordance with an equation U/L=ΔI/Δt wherein L is an inductance of the cable system at said device 1 and t is the time. In this case, when one or more loads are cut off, the inductance of the cable system will increase etc.

The circuits 11-16 may at least partly be realized via one or more processors and may at least partly be realized via hardware or software or a mixture of both etc.

Summarizing, devices 1 for detecting problems in cable systems with cables 4 and loads 5-8 comprise first circuits 11 for providing first signals to the cables 4, second circuits 12 for measuring parameters of second signals that are responses to the first signals, and third circuits 13 for detecting the problems in response to changes in values of the parameters. The loads 5-8 may comprise mutually parallel loads each showing a capacitive behavior. The problems may comprise interruptions in the cables 4 that result in changes in capacitances of the cable system and in the changes in the values of the parameters. The devices 1 may further comprise fourth circuits 14 for discharging the capacitances, fifth circuits 15 for deriving positions of the problems from the changes in the values of the parameters, and sixth circuits 16 for feeding at least one other circuit 11-15 and/or for activating at least one other circuit 11-15 in response to cable system information and/or timing information.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. A device for detecting a problem in a de-activated cable system, the cable system comprising a cable and loads connected to the cable, the device comprising
a first circuit for providing a first signal to the cable,
a second circuit for measuring a parameter of a second signal, the second signal being a response to the first signal, and
a third circuit for detecting the problem in the cable system in response to a change in a value of the parameter of the second signal, and
a fifth circuit for deriving a position of the problem from the change in the value of parameter of the second signal.

2. The device as defined in claim 1, the loads comprising mutually parallel loads electrically connected to the cable at mutually different locations, the mutually parallel loads each showing a capacitive behavior in the de-activated cable system.

3. The device as defined in claim 2, the problem in the cable system comprising an interruption in the cable of the cable system, the interruption resulting in a change in a capacitance of the cable system at said device, the change in the capacitance of the cable system at said device resulting in the change in the value of the parameter of the second signal.

4. The device as defined in claim 3, further comprising
a fourth circuit for discharging the capacitance.

5. (canceled)

6. The device as defined in claim 1, the first circuit being arranged to provide the first signal to the cable at first and second moments in time, the second circuit being arranged to measure the parameter of the second signal per moment in time, and the third circuit being arranged to compare values of this parameter of the second signal with each other.

7. The device as defined in claim 1, the first signal comprising a DC current signal and the second signal comprising a voltage signal.

8. The device as defined in claim 7, the DC current signal having a constant amplitude and the voltage signal comprising a slope.

9. The device as defined in claim 8, the parameter of the voltage signal defining an angle of the slope or defining an amount of time required for an amplitude of the voltage signal to change by a predefined value.

10. The device as defined in claim 9, the first circuit being arranged to provide the DC current signal to the cable at a first and second moments in time, the second circuit being arranged to measure the parameter of the voltage signal per moment in time, and the third circuit being arranged to compare values of this parameter of the voltage signal with each other.

11. The device as defined in claim 1, further comprising
a sixth circuit for feeding one or more of the other circuits and/or for activating one or more of the other circuits in response to cable system information and/or timing information.

12. A system comprising the device as defined in claim 1 and further comprising a station, a cable and/or a load.

13. A method for detecting a problem in a de-activated cable system, the cable system comprising a cable and loads connected to the cable, the method comprising steps of
providing a first signal to the cable,
measuring a parameter of a second signal, the second signal being a response to the first signal,
detecting the problem in the cable system in response to a change in a value of the parameter of the second signal and
deriving a position of the problem from the change in the value of the parameter of the second signal.

14. A computer program product for, when run on a computer, performing the steps of the method as defined in claim 13.

15. A medium for storing and comprising the computer program product as defined in claim 14.
